(19) United States
(12) Patent Application Publication
(10) Pub. No.: US 2002/0036286 A1
(43) Pub. Date: Mar. 28, 2002

(54) Gallium nitride based II-V group compound semiconductor device

(76) Inventors: Jin-Kuo Ho, Taipei City (TW); Chang-Shyang Jong, Hsinchu City (TW); Chien-Chia Chiu, Taipei City (TW); Tse-Jun Chen, Taipei City (TW)

Correspondence Address: LAW OFFICE OF LIAUH & ASSOC., 4224 WAIALAE AVE, STE 5-388, HONOLULU, HI, 96816

(21) Appl. No.: 09/572,505

(22) Filed: May 15, 2000

(30) Foreign Application Priority Data
Jan. 5, 2000 (TW) 89100082

(51) Int. Cl. H01L 29/12; H01L 29/06

(52) U.S. Cl. 257/11

(57) ABSTRACT

This specification discloses a gallium nitride-based III-V Group compound semiconductor device. Its p-type electrode consists of a semiconductor oxide film and a transparent conductive film. With the good ohmic contact between the former film and the p-type semiconductor layer, the latter one can homogeneously distribute the current to the surface of the whole p-type semiconductor layer. Since both the semiconductor oxide film and the transparent conductive film can be easily penetrated by light, the p-type electrode is a transparent structure with a transparency over 75% within the visible light range. Therefore, this invention can greatly increase the efficiency of the light-emitting devices. Moreover, the manufacturing procedure of this invention being simple and reliable, the yield and device reliability can thus be greatly raised. The production cost is lowered with simplified manufacturing steps at the same time.

### BACKGROUND OF THE INVENTION

1. Field of the Invention

The present invention relates to a gallium nitride based III-V Group compound semiconductor device and, more particularly, to a gallium nitride based III-V Group compound semiconductor light-emitting device which serves as the material for a transparent electrode on a p-type semiconductor layer.

2. Description of Related Art

Since in the structure of a gallium nitride (GaN) based light-emitting device, the carrier concentration (hole concentration) of the p-type semiconductor layer can not be effectively increased and the mobility of the hole carriers is small, the resistivity of the p-type semiconductor layer is very high. When a forward current is imposed on the device, the current is not easy to be homogeneously spreaded over the p-type semiconductor layer. The light-emitting area is limited to regions below and nearby the metal electrode, and the opaque metal electrode blocks most of the light; therefore, the light output efficiency of the GaN based light-emitting device is not high.

The above light-blocking problem can be resolved by applying a transparent electrode on the surface of the p-type semiconductor layer. Nichia Chemical Industries, LTD. proposed a double layer metal structure (e.g. Ni/Au double layer structure) as the transparent electrode. Its thickness is between 0.005 μm and 0.2 μm. A further thermal treatment is processed in an inert gas at temperatures above 400° C. to improve its properties. Furthermore, the Japanese Toyoda GoseiCo., also proposed the idea of using a thin metal layer as the transparent electrode of the p-type semiconductor layer. In addition to the change in the metal layer material (replacing Ni/Au by Co/Au or Pd/Au), it also features that the thermal treatment of the thin metal transparent electrode is processed in an atmosphere with oxygen. Besides, there are also other companies proposing similar methods of using a thin metal layer as the transparent electrode of the p-type GaN semiconductor layer. The differences among the above prior arts are on the choices of the materials of the metal layer, the changes in thermal treatment conditions, and improvements in the manufacture of electrodes.

Please refer to FIG. 1, which is a schematic view of the basic structure of a GaN based light-emitting device when using a thin metal layer as the p-type semiconductor layer transparent electrode. The structure comprises: a substrate 1, a n-type GaN semiconductor layer 2, a light-emitting active layer 8, a p-type GaN semiconductor layer 3, a transparent electrode (p-type electrode) 4, a n-type electrode 5, a p-type electrode pad 6 for electrical connection, and a passivation protective film 7. There are a few drawbacks when using a thin metal layer as the transparent electrode 4 of a GaN based light-emitting device. First, though the emitting light can penetrate the thin metal layer, most percentage of light is absorbed by the thin metal layer, thus the transparency is limited. Take the Ni/Au double metal structure as an example, as shown in FIG. 2. Even though the thickness is below 100 Å, the transparency (the vertical axis) only attains around 20˜40% in the visible light region with wavelengths (the horizontal axis) ranging from 350 nm to 750 nm, such as the curve 10 in the drawing. The transparency can only be increased to around 40˜75% even if a special thermal treatment is employed, such as the curve 20 in the drawing. Therefore, using a thin metal layer as the transparent electrode causes great loss in emitted light and lowers the light-emitting efficiency of the devices. Secondly, the thickness of the thin metal structure has to be below hundreds of Angstrom or even below 100 Å so that enough light can penetrate through for practical application. However, as the thickness decreases, the sheet resistance of the thin metal layer increases and causes poor spread of the current. Furthermore, using such thin metal structure as the transparent electrode makes the manufacturing procedure control difficult and the yield can not be increased. In addition, the homogeneity of thickness can not be readily controlled with precision, which in turn affects the homogeneity of emitted light. Lastly, the thin metal is easy to have reactions with oxygen and moisture in the environment to deteriorate. This drawback decreases the device lifetime and reliability; so an additional passivation protective layer 7 has to be formed for protecting the thin metal layer transparent electrode 4. Yet, this complicates the device structure and increases the production cost.

To sum up, in current GaN based light-emitting devices, there are still certain problems and defects when the thin metal layer as the p-type semiconductor transparent electrode is used according to the prior art. Thus, a further improvement is desired.

### SUMMARY OF THE INVENTION

In view of the foregoing, it is an object of the present invention to provide a GaN based III-V Group compound semiconductor device with a transparent electrode of high transparency for the manufacturing of highly efficient light-emitting devices.

The GaN based III-V Group compound semiconductor device provided pursuant to the above object is including: a substrate having first and second major surfaces; a semiconductor stacked structure arranged over the first major surface of the substrate and at least having a n-type semiconductor layer and a p-type semiconductor layer; a first electrode provided in electrical contact with the n-type semiconductor layer; and a second electrode provided in contact with the p-type semiconductor layer and including a semiconductor oxide layer and a transparent conducting layer, the semiconductor oxide layer establishing an ohmic contact with the p-type semiconductor layer and the transparent conducting layer forming on the semiconductor oxide layer.

It is another object of the present invention to provide a material structure for the p-type semiconductor layer transparent electrode in a GaN based light-emitting device so as to resolve the problems in the thin metal layer structure currently employed.

In this aspect, the present invention provides a transparent electrode for the GaN based III-V Group compound semiconductor device. The electrode includes a semiconductor oxide layer and a transparent conducting layer, wherein the semiconductor oxide layer forms an ohmic contact with the p-type GaN layer of the GaN based III-V Group compound semiconductor device and the transparent conducting layer forms on the semiconductor oxide layer.

To obtain a good transparent electrode, the new material structure should satisfy the following conditions:

(1) Transparency: the transparency should be higher than 75% in the visible light range with wavelengths from 350 nm to 750 nm;

(2) Conductivity: the formed structure should be conductive and form an ohmic contact with the p-type GaN semiconductor layer with a low interface resistance; and

(3) Stability: the formed structure should be stable against environment attack and avoid deterioration by structure change.

The thickness of the adopted semiconductor oxide layer is between 5 Å and 1.0 μm, and the transparent conducting layer can be a transparent conductive oxide layer, a transparent thin metal layer or a conductive metal nitride layer. If the transparent conducting layer is a transparent conductive oxide layer, the thickness is about 50 Å˜10 μm; if the transparent conducting layer is a transparent thin metal layer, the thickness is about 10 Å˜200 Å; and if the transparent conducting layer is a conductive metal nitride layer, the thickness is about 20 Å˜10 μm. The material structure serves as the transparent electrode in contact with the p-type semiconductor layer in the GaN based light-emitting device. In particular, the semiconductor oxide layer is to form a low resistance ohmic contact with the p-type GaN semiconductor and the transparent conducting layer homogeneously distributes the current over the surface of the whole p-type semiconductor layer. Since both the semiconductor oxide film and the transparent conducting film can be easily penetrated by light, the transparent electrode provided by the present invention has a transparency over 75% within the visible light range. Therefore, this invention can greatly increase the efficiency of the light-emitting devices. Moreover, the manufacturing procedure of this invention being simple and reliable, the yield and device reliability can thus be greatly improved. The production cost is lowered with simplified manufacturing steps at the same time.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow by illustration only, and thus is not limitative of the present invention, and wherein:

FIG. 1 depicts a schematic view of the basic structure of a GaN based light-emitting device when a thin metal layer as the transparent electrode in the prior art is used;

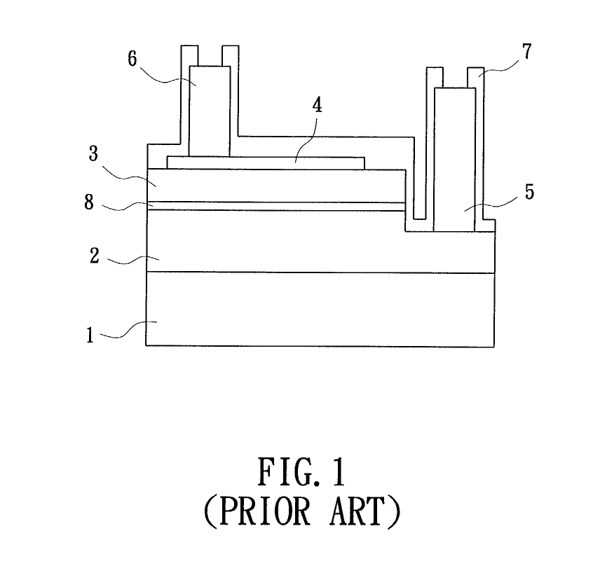

FIG. 2 depicts transparency of the transparent electrode when Ni (3 nm)/Au (7 nm) thin metal structure is used;

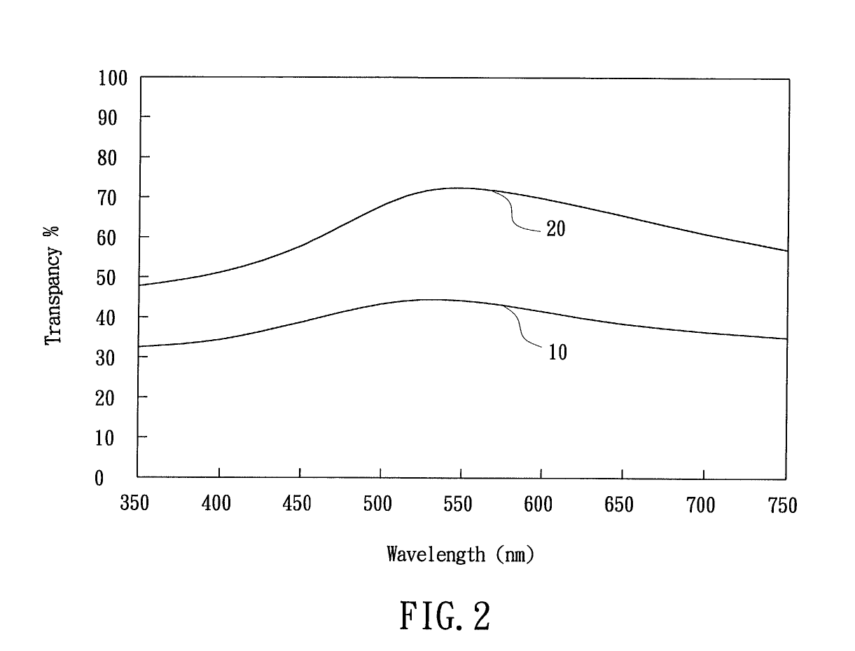

FIG. 3 depicts a schematic structure of a GaN based light-emitting device when a semiconductor oxide layer/transparent conducting layer is used as the transparent electrode according to the present invention; and

FIG. 4 depicts a transparency curve when the structure of the semiconductor oxide layer/transparent conductive layer is NiO (10 nm)/ITO (200 nm) according to the present invention.

### DETAILED DESCRIPTION OF THE INVENTION

The following description is mainly for a GaN based III-V Group compound light-emitting device.

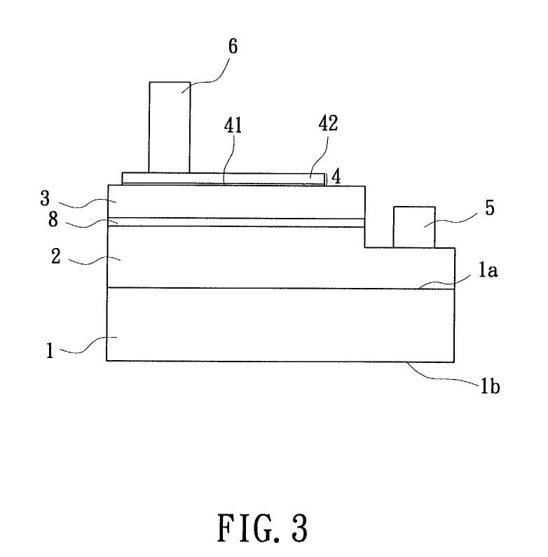

Referring to FIG. 3, a cross-sectional view of the aforementioned structure comprises a substrate 1, such as the substrate made of a sapphire, SiC, Si, ZnO, GaAs, GaN, LiGaO₂, LiAlO₂ or a spinel; a n-type semiconductor layer 2 provided on a first major surface 1a of the substrate 1 with a thickness of 0.5 to 10 μm; a light-emitting active layer 8 formed on the surface of the n-type semiconductor 2 with a thickness of 10 Å to 0.5 μm; and a p-type semiconductor layer 3 formed on the surface of the light-emitting active layer 8 with a thickness of 0.01 to 5 μm. All the n-type, p-type semiconductor layers 2, 3 and the light-emitting active layer 8 adopt a nitride semiconductor material with, for example, the composition AlₓGa_{y}In_{(1-x-y)}N, where 0≦x≦1, 0≦y≦1, and 0≦x+y≦1. The n-type semiconductor layer 2 is preferably doped with an n-type dopant, such as silicon (Si), germanium (Ge), selenium (Se), sulfur (S) or tellurium (Te), though a n-type dopant may not be doped thereinto. The p-type semiconductor layer 3 is preferably doped with a p-type dopant, such as beryllium (Be), magnesium (Mg), calcium (Ca), strontium (Sr), barium (Ba), carbon (C) or zinc (Zn).

The p-type semiconductor layer 3 and the light-emitting active layer 8 are partially etched away, together with a surface portion of the n-type semiconductor layer 2, to partially expose the surface of the n-type semiconductor layer 2. An n-type electrode 5 is formed on the exposed surface portion of the n-type semiconductor layer 2.

A p-type electrode 4 is formed to directly cover a most percentage surface of the p-type semiconductor layer 3. The p-type electrode 4 is a transparent electrode. A great amount of the light is emitted from this electrode. This p-type electrode conventionally comprises one or more metals selected from, for instance, gold (Au), nickel (Ni), platinum (Pt), aluminum (Al), cobalt (Co), tin (Sn), indium (In), chromium (Cr), and titanium (Ti). A metallic material achieving preferable ohmic characteristics contains at least two metals selected from chromium, nickel, gold, titanium, and platinum. A particularly preferable metallic material contains gold and nickel, with preferably a layer of nickel formed in direct contact with the p-type semiconductor layer 3 and a layer of gold formed on the nickel layer. Conventionally, the p-type electrode layer 4 made of ordinary metallic materials is further processed by an annealing treatment in an inert atmosphere. A preferable thickness of the final electrode is between 0.001 μm and 1 μm.

According to the invention, this p-type electrode layer 4 comprises a semiconductor oxide layer 41 and a transparent conductive layer 42 for providing the GaN based III-V Group compound light-emitting devices with an electrode with good light-transmitting ability. The function of the semiconductor oxide layer 41 is to serve as good ohmic contact with the p-type semiconductor layer 3, and the transparent conductive layer 42 provided on the semiconductor oxide layer 41 for distributing the current throughout the transparent electrode 4.

The above-mentioned semiconductor oxide 41 is an oxide of titanium (Ti), zirconium (Zr), hafnium (Hf), vanadium (V), niobium (Nb), tantalum (Ta), nickel (Ni), cobalt (Co), iron (Fe), palladium (Pd), manganese (Mn), molybdenum (Mo), chromium (Cr), tungsten (W), rhodium (Rh), lanthanum (La), copper (Cu), silver (Ag), ruthenium (Ru), Iridium (Ir), or yttrium (Y), such as NiO, CoO, Co₃O₄, FeO, PdO, MnO, MnO₄, MoO₂, Fe₃O₄, Fe₂O₃, Cr₂O₃, CrO, CrO₂, V₂O₅, WO₃, CuO, Cu₂O, Ag₂O, Y₂O₃, Rh₂O₃, CuAlO₂, SrCu₂O₂, etc. The thickness is between 5 Å and 1.0 μm. The transparent conductive layer 42 can be a transparent conductive oxide layer, a transparent thin metal layer, or a transparent conductive metal nitride layer. The conducting oxide can be, for example, tin-doped indium oxide (indium tin oxide, ITO), ZnO, In₂O₃, or SnO₂, with a thickness of 50 Å to 10 μm. The transparent thin metal can be titanium (Ti) zirconium (Zr), hafnium (Hf), vanadium (V), niobium (Nb), tantalum (Ta), chromium (Cr), molybdenum (Mo), tungsten (W), cobalt (Co), nickel (Ni), palladium (Pd), platinum (Pt), iridium (Ir), ruthenium (Ru), rhodium (Rh), copper (Cu), silver (Ag), gold (Au), and aluminum (Al), with a thickness of 10 Å to 200 Å. The transparent metal nitride is, for instance, a transition metal nitride (TMN), a TMN containing aluminum (TMₓAl₍₁₋ₓ₎N), a TMN containing gallium (TMₓGa₍₁₋ₓ₎N), or a TMN containing indium (TMₓIn₍₁₋ₓ₎N), wherein the transition metal (TM) is selected from Ti, Zr, Hf, V, Nb, Ta, Cr, Mo, or W. That is, the TMN is such as TiN, ZrN, HfN, VN, NbN, TaN, CrN, MoN, WN, TiAlN, ZrAlN, HfAlN, CrAlN, VAlN, etc. The thickness ranges from 20 Å to 10 μm.

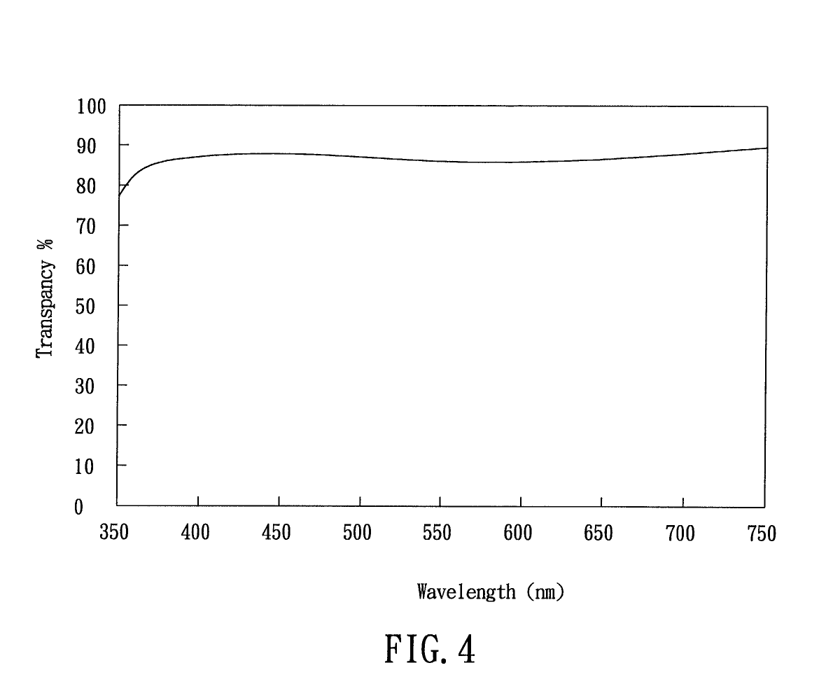

The p-type transparent electrode layer 4 of the present invention forms a good ohmic contact with the p-type semiconductor layer 3 through the semiconductor oxide layer 41. The transparent conductive layer 42 homogeneously distributes the current throughout the surface of the whole p-type semiconductor layer 3. Since both the semiconductor oxide layer 41 and the transparent conductive layer 42 have good light-transmitting ability, the transparent electrode structure proposed in the present invention reaches a transparency over 75% in the visible light region, as shown in FIG. 4. A p-type electrode pad 6 is formed on the transparent electrode layer 4.

The light-emitting device is then mounted on a first stem of lead frame (not shown) via a second major surface 1b of the substrate 1. A wire (not shown) is bonded onto the p-type electrode pad 6 and connected to a second stem of lead frame (not shown). The n-type electrode 5 connects to the first stem of lead frame via another wire, a light-emitting lamp is then formed after resin molding.

The invention being thus described, it will be obvious that the same may be varied in many ways. Such variations are not to be regarded as a departure from the spirit and scope of the invention. For example, this invention can be applied to the gallium nitride-based III-V Group semiconductor laser and the photo-detector. All such modifications as would be obvious to one skilled in the art are intended to be included within the scope of the following claims.

What is claimed is:

1. A gallium nitride-based III-V Group compound semiconductor device, which comprises:
a substrate having first and second major surfaces;
a semiconductor stacked structure arranged over the first major surface of the substrate, and comprising a n-type semiconductor layer and a p-type semiconductor layer;
a first electrode provided in electrical contact with the n-type semiconductor layer; and
a second electrode provided in contact with the p-type semiconductor layer which comprises a semiconductor oxide layer and a transparent conductive layer, the semiconductor oxide layer establishing an ohmic contact with the p-type semiconductor layer and the transparent conductive layer forming on the semiconductor oxide layer.

2. The device according to claim 1, wherein the semiconductor oxide layer is made of an oxide selected from the group comprising Ti, Zr, Hf, V, Nb, Ta, Ni, Co, Fe, Pd, Mn, Mo, Cr, W, Rh, La, Cu, Ag, Ru, Ir, and Y.

3. The device according to claim 2, wherein the semiconductor oxide layer is made of a compound selected from the group comprising NiO, CoO, Co₃O₄, FeO, PdO, MnO, MnO₄, MoO₂, Fe₃O₄, Fe₂O₃, Cr₂O₃, CrO, CrO₂, V₂O₅, WO₃, CuO, Cu₂O, Ag₂O, Y₂O₃, Rh₂O₃, CuAlO₂, and SrCu₂O₂.

4. The device according to claim 1, wherein the transparent conductive layer is a conductive oxide layer. is a conductive oxide layer.

5. The device according to claim 4, wherein the conductive oxide is selected from the group comprising ITO, ZnO, In₂O₃, and SnO₂.

6. The device according to claim 1, wherein the transparent conductive layer is a transparent thin metal layer.

7. The device according to claim 6, wherein the thin metal layer is selected from the group comprising Ti, Zr, Hf, V, Nb, Ta, Cr, Mo, W, Co, Ni, Pd, Pt, Ir, Ru, Rh, Cu, Ag, Au, and Al.

8. The device according to claim 1, wherein the transparent conductive layer is a metal nitride layer.

9. The device according to claim 8, wherein the metal nitride layer is selected from the group comprising a transition metal nitride (TMN), a TMN containing aluminum (TMₓAl₍₁₋ₓ₎N), a TMN containing gallium (TMₓGa₍₁₋ₓ₎N), and a TMN containing indium (TMₓIn₍₁₋ₓ₎N).

10. The device according to claim 9, wherein the transition metal (TM) is selected from the group comprising Ti, Zr, Hf, V, Nb, Ta, Cr, Mo, and W.

11. A light-transmitting electrode for a gallium nitride-based compound semiconductor device, the electrode comprises:
a semiconductor oxide layer forming an ohmic contact with the gallium nitride-based compound semiconductor device; and
a transparent conductive layer provided on the semiconductor oxide layer.

12. The light-transmitting electrode according to claim 11, wherein the semiconductor oxide layer is made of an oxide selected from the group comprising Ti, Zr, Hf, V, Nb, Ta, Ni, Co, Fe, Pd, Mn, Mo, Cr, W, Rh, La, Cu, Ag, Ru, Ir, and Y.

13. The light-transmitting electrode according to claim 12, wherein the semiconductor oxide layer is made of a compound selected from the group comprising NiO, CoO, Co₃O₄, FeO, PdO, MnO, MnO₄, MoO₂, Fe₃O₄, Fe₂O₃, Cr₂O₃, CrO, CrO₂, V₂O₅, WO₃, CuO, Cu₂O, Ag₂O, Y₂O₃, Rh₂O₃, CuAlO₂, and SrCu₂O₂.

14. The light-transmitting electrode according to claim 11, wherein the transparent conductive layer is a conductive oxide layer.

15. The light-transmitting electrode according to claim 14, wherein the conductive oxide layer is selected from the group comprising ITO, ZnO, In₂O₃, and SnO₂.

16. The light-transmitting electrode according to claim 11, wherein the transparent conductive layer is a thin metal layer.

17. The light-transmitting electrode according to claim 11, wherein the transparent conductive layer is a metal nitride layer.
